(19) United States
(12) Patent Application Publication
(10) Pub. No.: US 2026/0147968 A1
(43) Pub. Date: May 28, 2026

(54) SYSTEM AND METHOD OF PATTERN SELECTION FOR AUTOMATIC TEST PATTERN GENERATOR FOR IMPROVED IR DROP ANALYSIS

(71) Applicant: Samsung Electronics Co., Ltd., Gyeonggi-do (KR)

(72) Inventor: Ihab ZAIDAN, San Diego, CA (US)

(21) Appl. No.: 19/187,420

(22) Filed: Apr. 23, 2025

Related U.S. Application Data
(60) Provisional application No. 63/725,244, filed on Nov. 26, 2024.

(51) Int. Cl. G06F 30/31

(52) U.S. Cl. CPC G06F 30/31

(57) ABSTRACT

A system and a method of pattern selection are provided for use by an electronic design automation (EDA) automatic test pattern generator (ATPG) for improved intermediate resistance (IR) drop analysis. The method includes identifying, for each of a plurality of transitional delay fault (TDF) patterns, flip-flops (FFs) toggling during a capture window; identifying coordinates on a grid for each of the toggled FFs; generating a boundary around the toggled FFs; generating tiles within the boundary; determining a number of toggled FFs included within each of the tiles; and ranking the plurality of TDF patterns based on the number of toggled FFs included within each of the tiles of each of the plurality of TDF patterns.

### CROSS-REFERENCE TO RELATED APPLICATION

This application claims the priority benefit under 35 U.S.C. § 119 (e) of U.S. Provisional Application No. 63/725,244, filed on Nov. 26, 2024, the disclosure of which is incorporated by reference in its entirety as if fully set forth herein.

### TECHNICAL FIELD

The disclosure generally relates to semiconductor device testing. More particularly, the subject matter disclosed herein relates to improvements to pattern selection for use by an electronic design automation (EDA) automatic test pattern generator (ATPG) for improved intermediate resistance (IR) drop (or voltage drop) analysis.

### SUMMARY

An ATPG is an EDA method or device used to find an input (or test) pattern (or sequence) that, when applied to a digital circuit, enables automatic test equipment (ATE) to distinguish between correct circuit behavior and faulty circuit behavior caused by defects in the digital circuit. For example, the generated patterns may be used to test semiconductor devices, or to assist with determining the cause of failure.

Generally, the effectiveness of ATPG is measured by the number of modeled defects, or fault models, detectable and by the number of generated patterns. These metrics generally indicate test quality (higher with more fault detections) and test application time (higher with more patterns).

A defect is an error caused in a device during the manufacturing process. A fault model is a mathematical description of how a defect alters design behavior. The logic values observed at the device's primary outputs, while applying a test pattern to some device under test, are called the output of that test pattern. The output of a test pattern, when testing a fault-free device that works exactly as designed, is called the expected output of that test pattern. A fault is said to be detected by a test pattern if the output of that test pattern, when testing a device that has only that one fault, is different than the expected output.

However, ATPG can fail to find a test for a particular fault, e.g., it is possible that a detection pattern exists, but the algorithm cannot find one.

Additionally, the current methodology for selecting a transitional delay fault (TDF) pattern as an input to an EDA for IR drop analysis mainly relies on a switching activity report generated by an ATPG tool. More specifically, a switching activity report provides a total number of toggling flops during capture cycle per pattern. IR drop analysis is then conducted using a pattern with a highest number of toggling flops in the switching activity report. However, relying on the above-described switching activity report methodology still results in high frequency transitional patterns failing L V cc that can only be addressed by many iterations of ATPG diagnostics often over weeks and many flop maskings, which could potentially impact test coverage for a given pattern. Herein, L V cc is a margin added on top of V min, which is a minimum voltage at which a device is supposed to operate at. The margin L V cc is added to account for process, voltage, and temperature (PVT) variation. These types of critical issues are often not detected in pre tape-out (TO) analysis and are often only observed fabrication on to a silicon wafer.

The TO process is also a significant financial commitment. Once a design is taped out, masks required for production are created. These masks, which are used to transfer the design onto the silicon wafer during the fabrication process, are expensive to produce. As such, any errors discovered after TO can lead to the creation of a new set of masks, significantly increasing the costs.

To overcome these issues, systems and methods are described herein, which introduce a physical aware aspect into a process of identifying a highest switching activity pattern to be used for IR drop analysis.

For example, the systems and methods may uses an algorithm based on physical coordinates of flip-flops (FFs) toggling for a given pattern and a structure of a chip's power grid. That is, the chip's power grid may be divided into tiles, the number of FFs toggling per tile may be tracked.

In addition, information related to a distance between a cluster of tiles with minimum number of FFs toggling in each tile and relevant power bumps physical location on the grid may be used.

Further, the physical proximity of FFs toggling in ATPG patterns may be used for analysis, as well as the distance between a cluster of such FFs and a relevant power bump's physical location on a power grid.

The above approaches improve on previous methods because they are capable of identifying IR drop issues before TO, minimizing post-Si debugging and increasing coverage by eliminating potential masks related to FFs contributing to LV cc issue.

In an embodiment, a method of pattern selection is provided for use by an EDA ATPG for improved IR drop analysis. The method includes identifying, for each of a plurality of TDF patterns, FFs toggling during a capture window; identifying coordinates on a grid for each of the toggled FFs; generating a boundary around the toggled FFs; generating tiles within the boundary; determining a number of toggled FFs included within each of the tiles; and ranking the plurality of TDF patterns based on the number of toggled FFs included within each of the tiles of each of the plurality of TDF patterns.

In an embodiment, an apparatus is provided, which includes a processor; and a memory for storing instructions, which when executed by the processor, control the apparatus to perform a method of pattern selection for use by an electronic design automation (EDA) automatic test pattern generator (ATPG) for improved intermediate resistance (IR) drop analysis. The method includes identifying, for each of a plurality of TDF patterns, FFs toggling during a capture window; identifying coordinates on a grid for each of the toggled FFs; generating a boundary around the toggled FFs; generating tiles within the boundary; determining a number of toggled FFs included within each of the tiles; and ranking the plurality of TDF patterns based on the number of toggled FFs included within each of the tiles of each of the plurality of TDF patterns.

### BRIEF DESCRIPTION OF THE DRAWING

In the following section, the aspects of the subject matter disclosed herein will be described with reference to exemplary embodiments illustrated in the figures, in which:

FIG. 1 illustrates an example electronic device, according to an embodiment;

FIG. 2 illustrates a TFD pattern scan operation, according to an embodiment;

FIGS. 3A to 3E illustrate a method for identifying IR drop prone TDF patterns and selecting these patterns for IR drop analysis, according to an embodiment;

FIG. 4 illustrates an example of information included in a physical design (PD) input file, according to an embodiment;

FIG. 5 illustrates a correlation between number of tiles in a cluster with a maximum number of adjacent tiles and a number of failing instances, according to an embodiment; and

FIG. 6 is a flowchart illustrating a method for identifying IR drop prone TDF patterns, according to an embodiment.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. A Iso, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

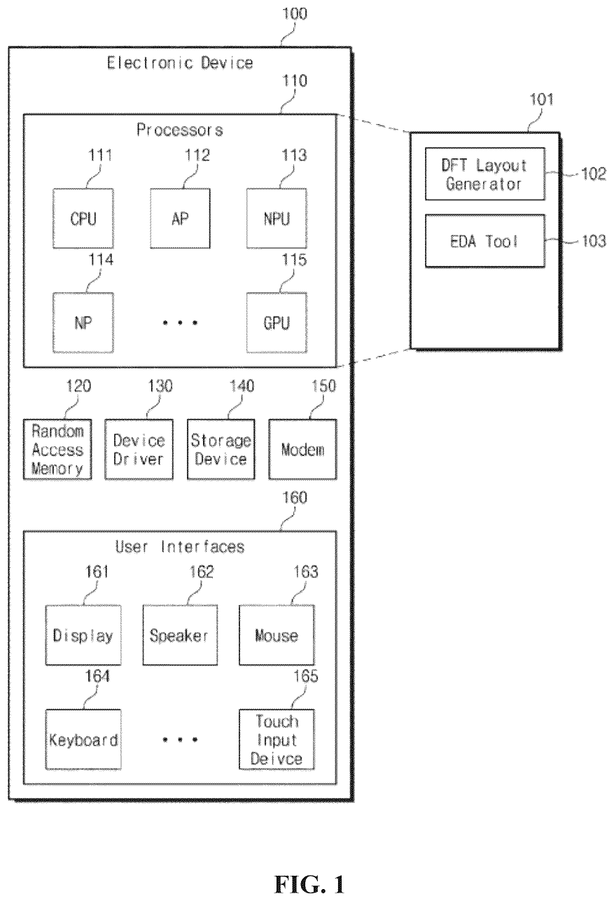

FIG. 1 illustrates an example electronic device, according to an embodiment.

Referring to FIG. 1, an electronic device 100 may include one or more processors 110, a random access memory (RAM) 120, a device driver 130, a storage device 140, a modem 150, and one or more user interfaces (UIs) 160.

The processors 110 may include, for example, at least one general-purpose processor such as a central processing unit (CPU) 111 or an application processor (AP) 112. Also, the processors 110 may further include at least one special-purpose processor such as a neural processing unit (NPU) 113, a neuromorphic processor (NP) 114, or a graphics processing unit (GPU) 115. The processors 110 may include two or more homogeneous processors; that is, although depicted as separate functional blocks, it is to be appreciated that two or more of the processors 111 through 115 may be combined into a single processor configured to perform the functions of the combined processors.

At least one of the processors 110 may drive a layout generation module 101. For example, the layout generation module 101 may be implemented in the form of instructions (or codes) that are executed by at least one of the processors 110. In this case, the at least one processor may load the instructions (or codes) of the layout generation module 101 into the random access memory 120.

For another example, at least one (or at least another) processor of the processors 110 may be configured to implement the layout generation module 101. For example, the at least one processor may be a dedicated hardware processor that implements functions of the layout generation module 101, thereby avoiding the need to download instructions or code into the random access memory 120 or other storage device.

The RAM 120 may be used as a working memory of the processors 110 and may be used as a main memory or a system memory of the electronic device 100. The random access memory 120 may include a volatile memory such as a dynamic random access memory or a static random access memory, or a nonvolatile memory such as a phase-change random access memory, a ferroelectric random access memory, a magnetic random access memory, or a resistive random access memory.

The random access memory 120 may store images that are necessary for the learning of the layout generation module 101. For example, the random access memory 120 may receive images from the storage device 140 or may receive images from an external device (e.g., a database, not explicitly shown) through the modem 150. The term “external device,” as may be used herein, is intended to refer broadly to any device that resides externally (i.e., outside) relative to the electronic device 100. More generally, any device (or functional block, circuit or module) that is outside of (i.e., external relative to) a given device, functional block, circuit or module may be considered an “external device.”

The device driver 130 may control the following peripheral devices depending on a request of the processors 110: the storage device 140, the modem 150, and the user interfaces 160. The storage device 140 may include a stationary storage device such as, but not limited to, a hard disk drive (HDD) or a solid-state drive (SSD), or a removable storage device such as an external HDD, an external SSD, a flash drive, or a removable memory card.

The storage device 140 may store images for the learning of the layout generation module 101. The images stored in the storage device 140 may be loaded into the RAM 120 and may be used for the learning of the layout generation module 101.

The modem 150 may provide remote communication with the external device. The modem 150 may perform wired or wireless communication with the external device. The modem 150 may communicate with the external device based on at least one of various communication schemes or protocols, such as, e.g., Ethernet, wireless-fidelity (Wi-Fi), long term evolution (LTE), and 5th generation (5G) mobile communication. The modem 150 may receive images for the learning of the layout generation module 101, from the external device, e.g., the database or other storage device. The modem 150 may load the received images into the random access memory 120.

The UIs 160 may receive information from a user and may provide information to a user. The UIs 160 may include at least one user output interface, such as, e.g., a display 161 or a speaker 162, and/or at least one user UI, such as, e.g., a mouse 163, a keyboard 164, or a touch input device 165.

The instructions (or codes) of the layout generation module 101 may be received through the modem 150 and may be stored in the storage device 140. The instructions (or codes) of the layout generation module 101 may be stored in a removable storage device, and the removable storage device may be coupled to the electronic device 100. The instructions (or codes) of the layout generation module 101 may be loaded and supplied to the random access memory 120 from the storage device 140.

The layout generation module 101 may include a design for test (DFT) layout generator 102 and an EDA tool 103. The DFT layout generator 102 may generate a DFT layout from a source (i.e., a circuit) layout of an electronic device to be manufactured, based on a given rule (e.g., a design rule check (DRC) output corresponding to the electronic device to be manufactured). The source layout may refer to a layout generated to perform specified functions that the electronic device intends to perform. The DFT layout may include constituent elements added to the source layout for the purpose of the structural test or elements converted from existing constituent elements.

The EDA tool 103 may generate test patterns appropriate for performing the structural test, based on a structure indicated by the DFT layout. For example, the EDA tool 103 may select two or more test targets and may generate two or more test patterns for each of the respective two or more test targets. The EDA tool 103 may include an ATPG.

The layout generation module 101 may allow the EDA tool 103 to generate a test pattern by generating the DFT layout from the source layout.

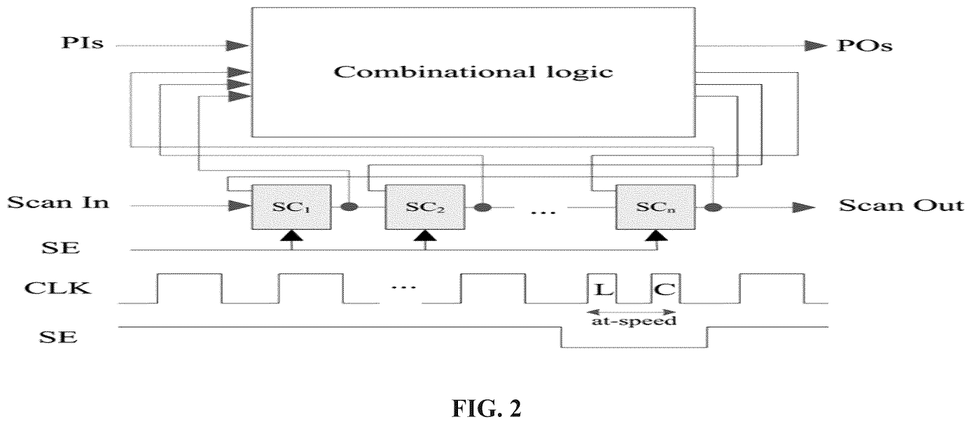

FIG. 2 illustrates a TFD pattern scan operation, according to an embodiment.

Referring to FIG. 2, the scan operation of a TFD pattern generally involves three stages, scan_in, scan_capture, and scan_out.

During scan_in, values used to test combinational logic are placed at scan chain FF inputs (SC₁ to SCₙ). During a capture window when scan enable (SE) goes low, a launch pulse (L) is issued followed by a capture pulse (C). The period of the two capture pulses represents a target frequency used to test logic for either a 1 to 0 or 0 to 1 transition, which depends on the type fault to be detected. The transition captured is shifted out during scan_out for comparison.

An ATPG tool tries to cover as many faults as possible with each TDF pattern, which means that a significant number of FFs in the design will toggle during that a capture window, resulting in IR drop.

According to an embodiment, a method is provided to identify IR drop prone TDF patterns and select these patterns for IR drop analysis using an EDA tool, e.g., the EDA tool 103 illustrated in FIG. 1.

According to an embodiment, the a TDF pattern may be selected based on physical coordinates of FFs toggling in a capture window for a given pattern, and a structure of a chip's power grid.

More specifically, the chip's power grid may be into tiles, and the number of FF toggles per tile is tracked.

In addition, information related to a distance between a cluster of flops toggling and a relevant power bumps physical location on the grid may be utilized.

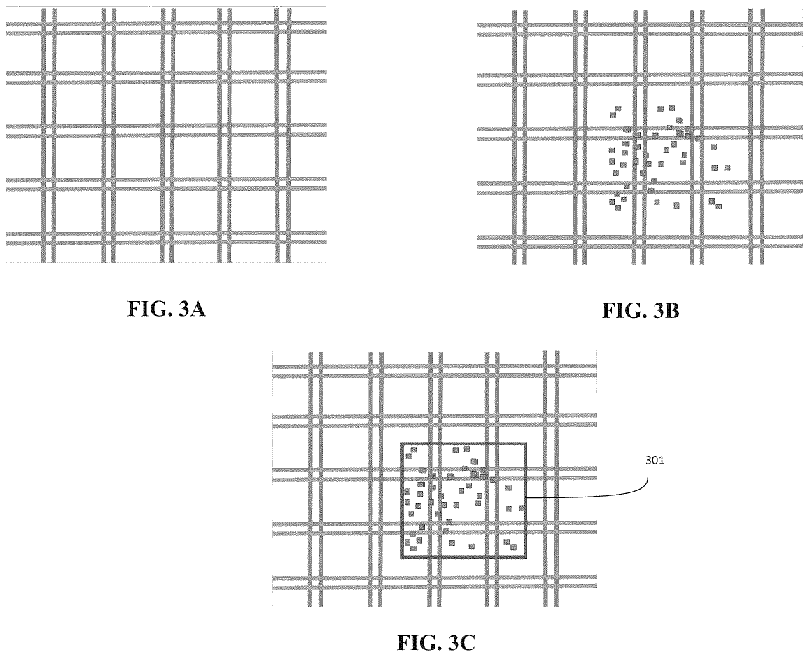

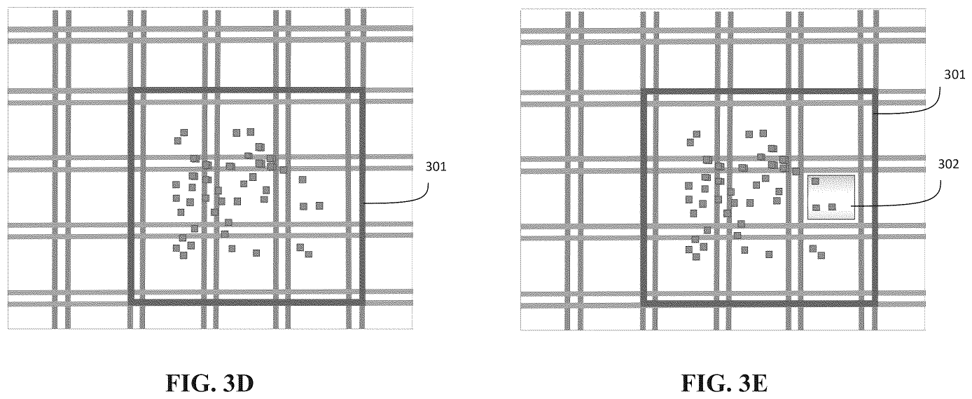

FIGS. 3A to 3E illustrate a method for identifying IR drop prone TDF patterns and selecting these patterns for IR drop analysis, according to an embodiment.

Referring to FIG. 3A, a power grid (PG) is formed by VDD and VSS lines, e.g., M etal 6 (M 6) and M 7 lines, respectively.

In FIG. 3B, FFs toggling are collected during a capture window for a TDF pattern, e.g., using an EDA tool, and coordinates for the toggled FFs are identified, e.g., using an IR drop analysis EDA tool.

In FIG. 3C, a boundary 301 containing all of the toggled FFs is created.

Thereafter, new boundary coordinates are calculated based on a physical design (PD) input file, and in FIG. 3D, the boundary 301 is snapped to the closest new coordinates overlaid on top of the PD PG.

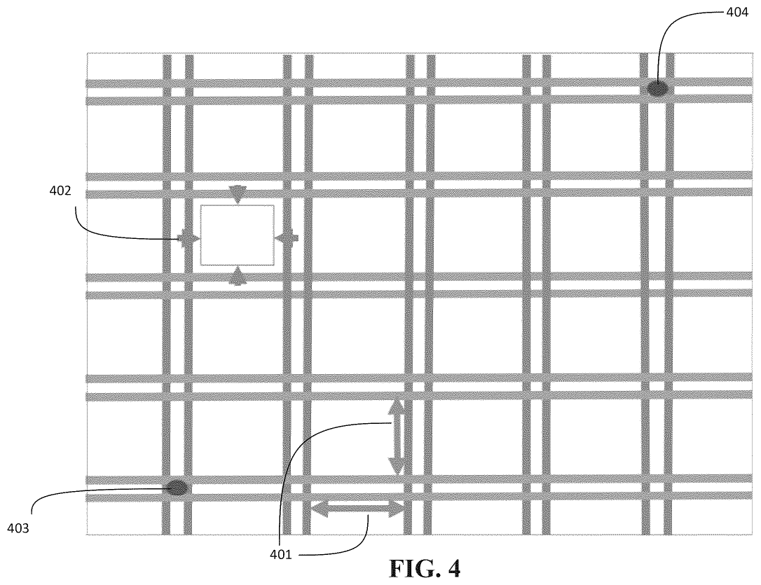

FIG. 4 illustrates an example of information included in a physical design (PD) input file, according to an embodiment.

Referring to FIG. 4, the information extracted from ICC and enter into a PD input filed may include dimensions 401 of box formed by VDD and VSS lines (e.g., M 6 and M 7), an offset 402 from the VDD and VSS lines to create a tile within each box, and PG coordinates 403 and 404.

Referring to FIG. 3E, tiles, e.g., tile 302, are created in the middle of each of the boxes formed by the VDD and VSS lines within the boundary 301.

Thereafter, the number of the toggled FFs per tile is determined.

The method illustrated in FIGS. 3A to 3E is then repeated for at least one other TDF pattern.

After completing the method illustrated in FIGS. 3A to 3E for multiple TDF patterns, the patterns may be ranked based on the number of the toggled FFs per tile.

More specifically, the patterns may be ranked based on a number of adjacent tiles including more than a predetermine number of the toggled FFs. For example, Table 1 below shows an example of pattern ranking based on chip analysis assuming an adjacent tile FF threshold of 20 FFs. The threshold of 20 FFs per tile is approximately 30% of a tile's area when considering M 6/M 7 VDD/VSS metal lines. Although the threshold may be variably set by a user, reducing or increasing this number may affect the resolution and/or make data interpretation more difficult.

TABLE 1

| | | | Max | | Adjacent | | | Cluster |
|---|---|---|---|---|---|---|---|---|
| | | # of | toggled | Tiles >20 | tiles >20 | | Cluster | distance |
| | Pattern | toggled | FFs | FFs | FFs | # of | size | from |
| Rank | # | FFs | per tile | toggled | toggled | clusters | (tiles) | WP (μ) |
| 1 | 462 | 8089 | 33 | 21 | 17 | 1 | 17 | 1134 |
| 2 | 30 | 8384 | 41 | 24 | 15 | 1 | 15 | 1051 |
| 34 | 325 | 8908 | 34 | 20 | 12 | 1 | 12 | 1051 |

As shown in Table 1 above, the first ranked pattern is #462, based on the number of adjacent tiles having more than 20 taggled FFs therein, the column of which is bolded. Based on conventional methodology, pattern #325 would be ranked first, based on having the highest number of toggled FFs. However, as described above, the conventional methodology fails to consider the physical proximity of FFs toggling as well as the distance between a cluster of such FFs and a relevant power bump's physical location on the power grid.

As illustrated in Table 1, the present disclosure considers the physical proximity of FFs toggling (i.e., the number of adjacent tiles having more than 20 taggled FFs therein) as well as the distance between a cluster of such FFs and a relevant power bump's physical location on the power grid (i.e., cluster distance from a weakest point (WP) on the chip). Herein, the WP on a chip is a position on the chip located farthest from all power supply nodes of the chip.

Although pattern #462 has a higher number of adjacent tiles than pattern #30, the number of failing instances related to pattern #30 is higher than pattern #462 due to the distance between the clusters and the WP.

Compared with the convention methodology, which merely selects patterns based on the highest number of toggled FFs, pattern selection based on the method illustrated in FIGS. 3A to 3E shows improved ability in selecting patterns that cause very high IR drop, allowing for improved TDF LV cc failure debugging throughput time.

Furthermore, selecting a pattern most likely to produce IR drop violations may also expose holes in a PG and/or may be used to identity missing vias, thereby presenting opportunities to optimize the PG where additional VDD and VSS straps may be added to address some of these violations.

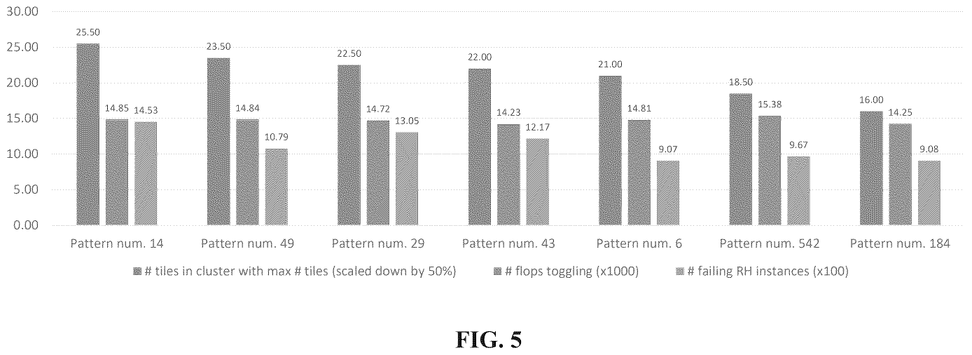

FIG. 5 illustrates a correlation between number of tiles in a cluster with a maximum number of adjacent tiles and a number of failing instances, according to an embodiment.

Referring to FIG. 5, for each pattern #, the left most bar represents the number of tiles in a cluster with the maximum number of adjacent tiles, the middle bar represents the number of toggled FFs, and the right most bar represents the number of software related failing instances detected through a conventional procedure.

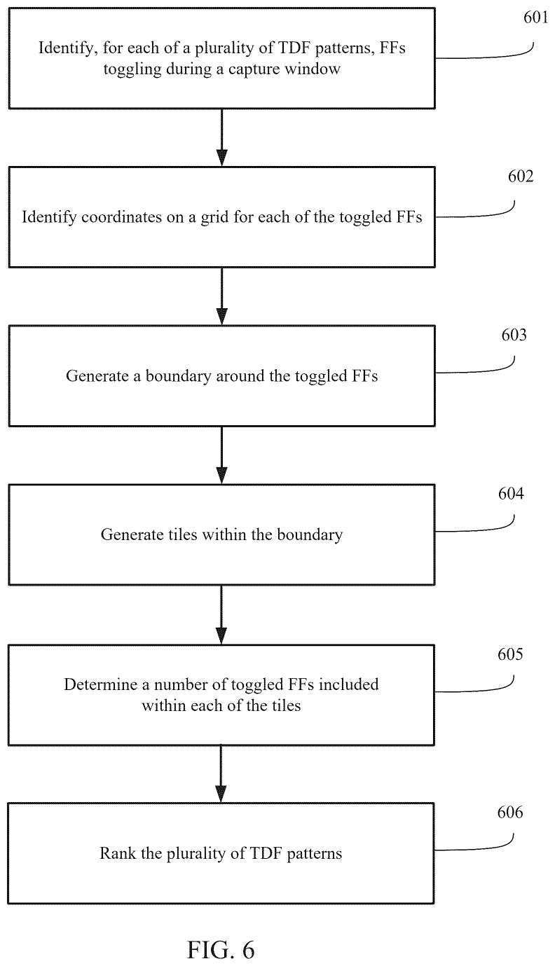

As illustrated in FIG. 5, a current approach of picking a VCD file for IR drop analysis, which is based on a number of toggled FFs (i.e., the middle bar) would pick pattern #542. However, local switching analysis (LSA) run for the total number of adjacent tiles with greater than 20 FFs each (i.e., the left most bar) points to pattern 14 as a better candidate for IR drop analysis. Additional, lab analysis data supports this conclusion. FIG. 6 is a flowchart illustrating a method for identifying IR drop prone TDF patterns, according to an embodiment.

Referring to FIG. 6, in step 601, an EDA ATPG identifies, for each of a plurality of TDF patterns, FFs toggling during a capture window.

In step 602, the EDA ATPG identifies coordinates on a grid for each of the toggled FFs.

In step 603, the EDA ATPG generates a boundary around the toggled FFs.

In step 604, the EDA ATPG generates tiles within the boundary.

In step 605, the EDA ATPG determines a number of toggled FFs included within each of the tiles.

In step 606, the EDA ATPG ranks the plurality of TDF patterns based on the number of toggled FFs included within each of the tiles of each of the plurality of TDF patterns. Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A method of pattern selection for use by an electronic design automation (EDA) automatic test pattern generator (ATPG) for improved intermediate resistance (IR) drop analysis, the method comprising:
identifying, for each of a plurality of transitional delay fault (TDF) patterns, flip-flops (FFs) toggling during a capture window;
identifying coordinates on a grid for each of the toggled FFS;
generating a boundary around the toggled FFS;
generating tiles within the boundary;
determining a number of toggled FFs included within each of the tiles; and
ranking the plurality of TDF patterns based on the number of toggled FFs included within each of the tiles of each of the plurality of TDF patterns.

2. The method of claim 1, wherein generating a boundary around the toggled FFs comprises:
generating the boundary to surround each of the toggled FFS;
calculating new coordinates for the boundary based on a physical design (PD) input file; and
snapping the boundary to the closest new coordinates overlaying a PD grid.

3. The method of claim 2, wherein the PD input file includes at least one of:
dimensions of a box formed by VDD and VSS lines,
an offset from the VDD and the VSS lines to create a tile within each box, or PD grid coordinates.

4. The method of claim 1, wherein generating tiles within the boundary comprises generating a tile within a box formed by VDD and VSS lines within the boundary.

5. The method of claim 4, wherein the tile if formed in a middle of the box, offset from each of the VDD and VSS lines by a predetermined distance.

6. The method of claim 4, wherein the VDD lines include metal 6 and VSS lines include metal 7.

7. The method of claim 1, wherein ranking the plurality of TDF patterns based on the number of toggled FFs included within each of the tiles of each of the plurality of TDF patterns comprises:
determining, for each of the plurality of TDF patterns, a number of adjacent tiles having more than N toggled FFs therein; and
ranking the plurality of TDF patterns based on their respective number of adjacent tiles having more than N toggled FFs therein.

8. The method of claim 7, wherein N equals 20.

9. The method of claim 7, wherein the plurality of TDF patterns are ranked further based on a distance of the adjacent tiles having more than N toggled FFs therein to a weak point of a chip.

10. The method of claim 9, wherein the weak point of the chip is located farthest from all power supplies of the chip.

11. An apparatus comprising:
a processor; and
a memory for storing instructions, which when executed by the processor, control the apparatus to perform a method of pattern selection for use by an electronic design automation (EDA) automatic test pattern generator (ATPG) for improved intermediate resistance (IR) drop analysis, the method comprising:
identifying, for each of a plurality of transitional delay fault (TDF) patterns, flip-flops (FFs) toggling during a capture window;
identifying coordinates on a grid for each of the toggled FFs;
generating a boundary around the toggled FFS;
generating tiles within the boundary;
determining a number of toggled FFs included within each of the tiles; and
ranking the plurality of TDF patterns based on the number of toggled FFs included within each of the tiles of each of the plurality of TDF patterns.

12. The apparatus of claim 11, wherein generating a boundary around the toggled FFs comprises:
generating the boundary to surround each of the toggled FFs;
calculating new coordinates for the boundary based on a physical design (PD) input file; and
snapping the boundary to the closest new coordinates overlaying a PD grid.

13. The apparatus of claim 12, wherein the PD input file includes at least one of:
dimensions of a box formed by VDD and VSS lines,
an offset from the VDD and the VSS lines to create a tile within each box, or PD grid coordinates.

14. The apparatus of claim 11, wherein generating tiles within the boundary comprises generating a tile within a box formed by VDD and VSS lines within the boundary.

15. The apparatus of claim 14, wherein the tile if formed in a middle of the box, offset from each of the VDD and VSS lines by a predetermined distance.

16. The apparatus of claim 14, wherein the VSS lines include metal 6 and VDD lines include metal 7.

17. The apparatus of claim 11, wherein ranking the plurality of TDF patterns based on the number of toggled FFs included within each of the tiles of each of the plurality of TDF patterns comprises:
determining, for each of the plurality of TDF patterns, a number of adjacent tiles having more than N toggled FFs therein; and
ranking the plurality of TDF patterns based on their respective number of adjacent tiles having more than N toggled FFs therein.

18. The apparatus of claim 17, wherein N equals 20.

19. The apparatus of claim 17, wherein the plurality of TDF patterns are ranked further based on a distance of the adjacent tiles having more than N toggled FFs therein to a weak point of a chip.

20. The apparatus of claim 19, wherein the weak point of the chip is located farthest from all power supplies of the chip.
